(19) United States
(12) Patent Application Publication
(10) Pub. No.: US 2025/0151290 A1
(43) Pub. Date: May 8, 2025

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Sang Soo LEE, Gyeonggi-do (KR); Jae Hyun HAN, Gyeonggi-do (KR)

(21) Appl. No.: 18/397,691

(22) Filed: Dec. 27, 2023

(30) Foreign Application Priority Data
Nov. 2, 2023 (KR) 10-2023-0149968

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80895; H01L 2224/80896; H01L 2924/1431; H01L 2924/14511

(57) ABSTRACT

A semiconductor device may include stacked first gate lines, stacked second gate lines, a channel structure extending through the first gate lines and the second gate lines, first contact plugs extending through the first gate lines and respectively connected to front surfaces of the first gate lines, and second contact plugs extending through the second gate lines and respectively connected to rear surfaces of the second gate lines.

### CROSS-REFERENCE TO RELATED APPLICATION

This application claims priority under 35 U.S.C. § 119 to Korean Patent Application No. 10-2023-0149968 filed on Nov. 2, 2023, which is incorporated herein by reference in its entirety.

### BACKGROUND

### 1. Technical Field

The present disclosure relates to an electronic device, and more particularly, to a semiconductor device and a method of manufacturing the semiconductor device.

### 2. Related Art

An integration degree of a semiconductor device is mainly determined by an area occupied by a unit memory cell. Recently, as improvement in the integration degree of two-dimensional semiconductor devices in which memory cell are formed as a single layer on a substrate reach a limit, three-dimensional (3-D) semiconductor devices in which memory cells are stacked in multiple levels over a substrate have been proposed. In addition, extensive research efforts are expended for developing 3-D semiconductor devices with improved operational reliability and for improving the methods of manufacturing the 3-D semiconductor devices.

### SUMMARY

According to an embodiment of the present invention disclosure, a semiconductor device may include a first group of stacked first gate lines, and a second group of stacked second gate lines overlapping with the first group of the first stacked lines, the first and second groups being spaced apart from each other, wherein the first gate lines and the second gate lines alternate with insulation layers, a channel structure extending through the first gate lines and the second gate lines, first contact plugs extending through the first gate lines and respectively connected to front surfaces of the first gate lines, and second contact plugs extending through the second gate lines and respectively connected to rear surfaces of the second gate lines.

According to an embodiment of the present disclosure, a semiconductor device may include a peripheral circuit, a gate structure including a front surface facing the peripheral circuit, a first contact plug extending into the gate structure through a front surface, a second contact plug extending into the gate structure through a rear surface, and an interconnection structure connecting the first contact plug and the second contact plug to the peripheral circuit.

According to an embodiment of the present disclosure, a method of manufacturing a semiconductor device may include forming a gate structure including stacked first gate lines and stacked second gate lines, forming first contact plugs extending into the gate structure through a front surface and respectively connected to the first gate lines, and forming second contact plugs extending into the gate structure through a rear surface and respectively connected to the second gate lines.

These and other features and advantages of the present invention will become apparent from the following detailed description and drawings of example embodiments.

### BRIEF DESCRIPTION OF THE DRAWINGS

FIG. 1 is a simplified diagram illustrating a structure of a semiconductor device according to an embodiment of the present disclosure.

FIGS. 2A and 2B are simplified diagrams illustrating a structure of a semiconductor device according to an embodiment of the present disclosure.

FIGS. 3A to 3J are simplified diagrams illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure, an improved characteristic, and an improved integration degree.

An integration degree of a semiconductor device may be improved by stacking memory cells in a three dimension. In addition, a semiconductor device with a stable structure and improved reliability may be provided.

Hereinafter, embodiments of the present disclosure are described with reference to the accompanying drawings.

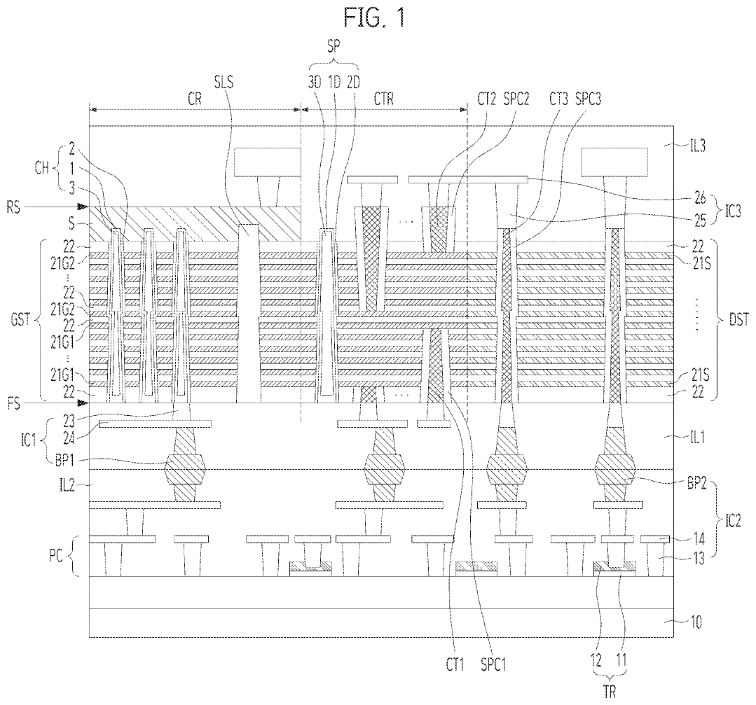

FIG. 1 is a simplified diagram illustrating a structure of a semiconductor device according to an embodiment of the present disclosure.

Referring to FIG. 1, the semiconductor device may include a gate structure GST, first contact plugs CT1, and second contact plugs CT2. The semiconductor device may further include at least one of a substrate 10, a transistor TR, a dummy stack DST, a third contact plug CT3, a first insulating spacer SPC1, a second insulating spacer SPC2, a third insulating spacer SPC3, a channel structure CH, a slit structure SLS, a support SP, a source structure S, a first interconnection structure IC1, a second interconnection structure IC2, a third interconnection structure IC3, a first interlayer insulating layer IL1, a second interlayer insulating layer IL2, and a third interlayer insulating layer IL3.

The gate structure GST may include stacked first gate lines 21G1 and stacked second gate lines 21G2. In some embodiments, the gate structure GST may include the first gate lines 21G1 and insulating layers 22 alternately stacked. The gate structure GST may also include the second gate lines 21G2 and insulating layers 22 alternately stacked. The first gate lines 21G1 and the second gate lines 21G2 may be word lines, source selection lines, drain selection lines, and the like. The first gate lines 21G1 and the second gate lines 21G2 may include a conductive material such as polysilicon, tungsten, or molybdenum.

The gate structure GST may include a front surface FS and a rear surface RS. The front surface FS of the gate structure GST and a peripheral circuit PC may be positioned to face each other. The source structure S may be positioned over or on the rear surface RS of the gate structure GST. In the illustrated embodiment of FIG. 1, the source structure S is positioned on the rear surface RS of the gate structure GST and is in direct contact with the rear surface RS of the gate structure GST. The first gate lines 21G1 may be positioned closer to the front surface FS of the gate structure GST, and the second gate lines 21G2 may be positioned closer to the rear surface RS of the gate structure GST. The first gate lines 21G1 may be grouped together to form a first group positioned closer to the front surface FS of the gate structure GST. The second gate lines 21G2 may be grouped together to form a second group positioned closer to the rear surface RS of the gate structure GST. The number of first gate lines 21G1 and the number of second gate lines 21G2 may be equal to or different from each other. The number of the first gate lines 21G1 and the number of the second gate lines 21G2 may change based on design considerations. Also, the sum of the number of the first and second gate lines 21G1 and 21G2 may change according to an integration degree of the semiconductor device. Integration degree as this term is used here means the integration density, i.e., the number of components that can be integrated into the semiconductor device. Higher integration degree (or integration density) is desirable because it leads to more powerful and compact devices.

The gate structure GST may include a cell region CR where memory cells are stacked and a contact region CTR where an interconnection structure is positioned. The interconnection structure may provide a pathway through which a bias signal (e.g., a voltage or a current) for driving the stacked memory cells is transferred. The interconnection structure may include one or more contact plugs, one or more conductive lines, and the like.

The source structure S may be positioned over or on the gate structure GST. In the illustrated embodiment of FIG. 1, the source structure S is positioned on the gate structure GST and is in direct contact with the gate structure GST.

The source structure S may cover the cell region CR of the gate structure and expose the contact region CTR. The source structure S may include a conductive material such as polysilicon or metal. In some embodiments, the source structure S may cover at least a portion of the contact region CTR or may cover at least a portion of the dummy stack DST.

The channel structure CH may extend through the gate structure GST. In the cell region CR, the channel structure CH may pass through the gate structure GST and extend from the front surface FS into the source structure S. The channel structure CH may include at least one of a channel layer 1, a memory layer 2, and an insulating core 3. The memory layer 2 may include at least one of a tunneling layer, a data storage layer, and a blocking layer. The data storage layer may include a floating gate, polysilicon, a charge trap material, nitride, a variable resistance material, and the like.

The slit structure SLS may extend through the gate structure GST. In the cell region CR, the slit structure SLS may pass through the gate structure GST and may extend from the front surface FS into the source structure S. The slit structure SLS may extend from the cell region CR to the contact region CTR. The slit structure SLS may include at least one of an insulating material, a semiconductor material, and a conductive material. In some embodiments, the slit structure SLS may include a gap-fill material such as an oxide layer, a nitride layer, or amorphous silicon. The slit structure SLS may include a source contact structure electrically connected to the source structure S and an insulating spacer surrounding a sidewall of the source contact structure.

The support SP may extend through the contact region CTR of the gate structure GST. The support SP may have a structure similar to the channel structure CH and may be a dummy channel structure. In some embodiments, the support SP may include at least one of a dummy channel layer 1D, a dummy memory layer 2D, and a dummy insulating core 3D.

The first contact plugs CT1 may extend through the contact region CTR of the gate structure GST. The first contact plugs CT1 may extend from the front surface FS of the gate structure GST into the gate structure GST. The first contact plugs CT1 may extend through the first gate lines 21G1 and may be respectively connected to front surfaces of the first gate lines 21G1. The first contact plugs CT1 may extend in different depths and may be electrically connected to the first gate lines 21G1, respectively. The first insulating spacers SPC1 may respectively surround sidewalls of the first contact plugs CT1. The first contact plugs CT1 may have a taper shape cross-section. In some embodiments, the first contact plug CT1 may have a portion closer to the front surface FS having a width greater than that of a portion closer to the rear surface RS.

Among the first contact plugs CT1, the first contact plug CT1 positioned farther from the cell region CR may have a height greater than that of the first contact plug CT1 positioned closer to the cell region CR. In some embodiments, the first contact plugs CT1 may be arranged so that a height increases as a distance from the cell region CR increases. However, the invention is not limited to this configuration only, and in some embodiments the first contact plugs CT1 may be arranged according to other configurations.

The second contact plugs CT2 may extend through the contact region CTR of the gate structure GST. The second contact plugs CT2 may extend from the rear surface RS of the gate structure GST into the gate structure GST. The second contact plugs CT2 may extend through the second gate lines 21G2 and may be respectively connected to rear surfaces of the second gate lines 21G2. The second contact plugs CT2 may extend in different depths and may be electrically connected to the second gate lines 21G2, respectively. The second insulating spacers SPC2 may respectively surround sidewalls of the second contact plugs CT2. The second contact plugs CT2 may have a taper shape cross-section. In some embodiments, the second contact plug CT2 may have a portion closer to the rear surface RS having a width greater than that of a portion closer to the front surface FS. In some embodiments, the first contact plugs CT1 may have a taper shape cross-section, and the second contact plugs CT2 may have an inverted taper shape cross-section.

Among the second contact plugs CT2, a second contact plug CT2 positioned closer to the cell region CR may have a height greater than that of a second contact plug CT2 positioned farther from the cell region CR. In some embodiments, the second contact plugs CT2 may be arranged so that a height increases as a distance from the cell region CR is decreased. However, the invention is not limited to this configuration only, and in some embodiments, the second contact plugs CT2 may be arranged according to other configurations.

The first contact plugs CT1 and the first gate lines 21G1 may be respectively connected in a one-to-one correspondence, meaning, that the number of the first gate lines 21G1 and the number of the first contact plugs CT1 may be the same. The second contact plugs CT2 and the second gate lines 21G2 may be respectively connected in a one-to-one correspondence, hence meaning that the number of the second gate lines 21G2 and the number of the second contact plugs CT2 may be the same. The number of first contact plugs CT1 and the number of second contact plugs CT2 may be equal to or different from each other. A sum of the number of the first gate lines 21G1 and the second gate lines 21G2 may be equal to the sum of the number of the first contact plugs CT1 and the second contact plugs CT2.

The first contact plugs CT1 and the second contact plugs CT2 may be positioned to correspond to each other. In some embodiments, the first contact plugs CT1 may be respectively positioned under the second contact plugs CT2. For example, the first contact plug CT1 having a relatively greater height may be arranged to correspond to or align with the second contact plug CT2 having a relatively lesser height. Accordingly, the first contact plugs CT1 and the second contact plugs CT2 may be symmetrically arranged. However, the invention is not limited to this configuration only, and in some embodiments the first and second contact plugs CT1 and CT2 may be asymmetrically arranged.

The dummy stack DST may include sacrificial layers 21S and insulating layers 22 which are alternately stacked. The sacrificial layers 21S may remain without being replaced with gate lines during the manufacturing process. In some embodiments, the sacrificial layers 21S may include nitride and the insulating layers 22 may include oxide. The gate structure GST and the dummy stack DST may be connected to each other and may share the insulating layers 22.

The third contact plugs CT3 may extend through the dummy stack DST. The third insulating spacers SPC3 may surround the sidewall of the third contact plugs CT3. The third contact plugs CT3 may pass through the dummy stack DST and may be connected to the second contact plugs CT2 via the third interconnection structures IC3. In some embodiments, the third contact plugs CT3 may pass through the contact region CTR instead of passing through the dummy stack DST.

The peripheral circuit PC may be positioned over or on the substrate 10. The peripheral circuit PC may include, for example, a page buffer, a row decoder, a logic circuit, an input/output circuit, and the like. The row decoder may include a pass transistor that controls a connection of a global line and a local line. The peripheral circuit PC may include a transistor TR, and the transistor TR may include a gate insulating layer 11 and a gate electrode 12.

The first interconnection structure IC1 may be positioned in the first interlayer insulating layer IL1 and may include at least one via 23 and at least one conductive line 24. The first interconnection structure IC1 may be positioned under the gate structure GST and may be connected to at least one of the channel structures CH, the first contact plugs CT1, and the third contact plugs CT3. The first interconnection structure IC1 may include a first bonding pad BP1.

The second interconnection structure IC2 may be positioned in the second interlayer insulating layer IL2 and may be electrically connected to the peripheral circuit PC. The second interconnection structure IC2 may include at least one via 13 and at least one conductive line 14. The second interconnection structure IC2 may include a second bonding pad BP2.

The third interconnection structure IC3 may be positioned in the third interlayer insulating layer IL3 and may include at least one via 25 and at least one conductive line 26. The third interconnection structure IC3 may be positioned on the gate structure GST and may be connected to at least one of the source structure S, the second contact plug CT2, and the third contact plug CT3.

A cell array and the peripheral circuit PC may be electrically connected by the first interconnection structure IC1, the second interconnection structure IC2, and the third interconnection structure IC3. The second contact plug CT2 and the first interconnection structure IC1 may be connected through the third contact plug CT3. The first interconnection structure IC1 and the second interconnection structure IC2 may be connected through the first bonding pad BP1 and the second bonding pad BP2, and the third contact plug CT3 and the peripheral circuit PC may be connected through the first interconnection structure IC1 and the second interconnection structure IC2. Through this, the second contact plugs CT2 may be electrically connected to the peripheral circuit PC. The channel structure CH may be connected to the peripheral circuit PC through the first interconnection structure IC1 and the second interconnection structure IC2.

According to the structure described above, the first contact plugs CT1 and the second contact plugs CT2 may be disposed on the front surface FS and the rear surface RS of the gate structure GST in a dispersion manner. Therefore, compared to a case where the first contact plugs CT1 and the second contact plugs CT2 are disposed only on the front surface FS, a height of the first contact plugs CT1 and the second contact plugs CT2 may be decreased. In addition, the area of the contact region CTR may be reduced.

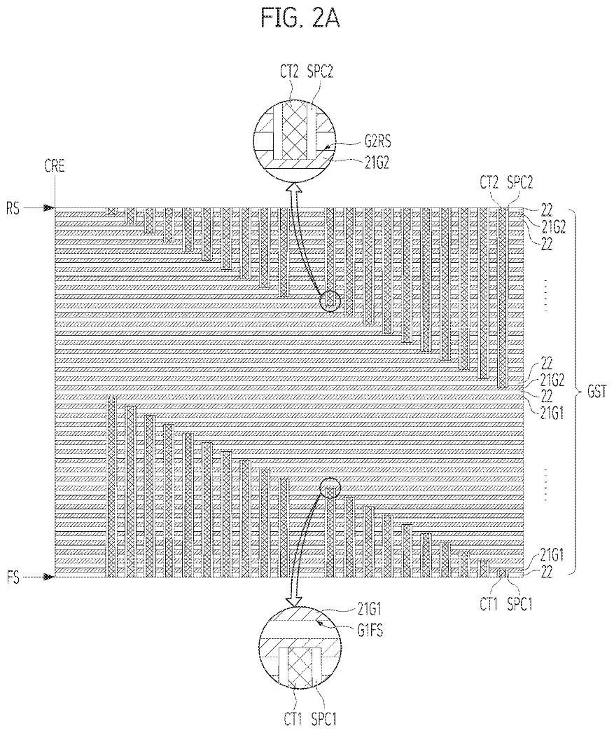

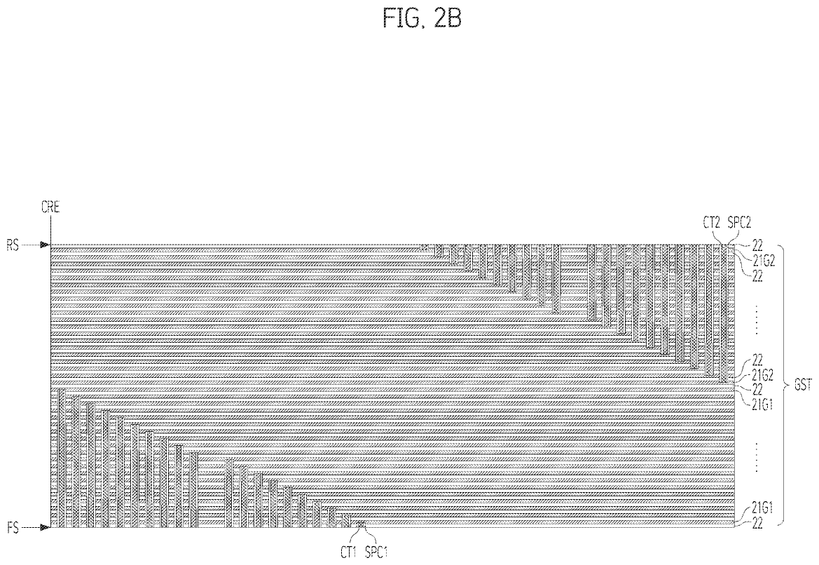

FIGS. 2A and 2B are simplified diagrams illustrating a structure of a semiconductor device according to an embodiment of the present disclosure. Hereinafter, a description overlapping a content described above may be omitted.

Referring to FIGS. 2A and 2B, the semiconductor device may include a gate structure GST, first contact plugs CT1, and second contact plugs CT2. The gate structure GST may include first gate lines 21G1 and insulating layers 22 alternately stacked, and may include second gate lines 21G2 and insulating layers 22 alternately stacked.

The first contact plugs CT1 may extend into the gate structure GST through the front surface FS of the gate structure GST and may be respectively connected to the first gate lines 21G1. The first contact plug CT1 may be connected to a front surface GIFS of the first gate line 21G1. In some embodiments, the first contact plug CT1 may be in contact with the front surface G1FS or may be connected to the first gate line 21G1 through the front surface G1FS. The second contact plugs CT2 may extend into the gate structure GST through the rear surface RS of the gate structure GST and may be respectively connected to the second gate lines 21G2. The second contact plug CT2 may be connected to a rear surface G2RS of the second gate line 21G2. In some embodiments, the second contact plug CT2 may be in contact with the rear surface G2RS or may be connected to the second gate line 21G2 through the rear surface G2RS.

Among the first contact plugs CT1, the first contact plug CT1 positioned farther from a cell region edge CRE may have a height less than that of the first contact plug CT1 positioned closer to the cell region edge CRE. In some embodiments, the first contact plugs CT1 may be arranged so that a height is decreased as a distance from the cell region edge CRE increases. However, the present disclosure is not limited thereto, and the height may be decreased as the distance from the cell region edge CRE decreases, or the first contact plugs CT1 may be randomly arranged regardless of the distance from the cell region edge CRE.

Among the second contact plugs CT2, the second contact plug CT2 positioned closer to the cell region edge CRE may have a height less than that of the second contact plug CT2 positioned farther from the cell region edge CRE. In some embodiments, the second contact plugs CT2 may be arranged so that a height is decreased as a distance from the cell region edge CRE decreases. However, the present disclosure is not limited thereto, and the height may be increased as the distance from the cell region edge CRE decreases, or the second contact plugs CT2 may be randomly arranged regardless of the distance from the cell region edge CRE.

In some embodiments, the first contact plugs CT1 may be arranged so that the height is decreased as the distance from the cell region edge CRE increases, and the second contact plugs CT2 may be arranged so that the height is decreased as the distance from the cell region edge CRE decreases. In other embodiments, the first contact plugs CT1 may be arranged so that the height is increased as the distance from the cell region edge CRE increases, and the second contact plugs CT2 may be arranged so that the height is increased as the distance from the cell region edge CRE decreases. The first contact plugs CT1 and the second contact plugs CT2 may be randomly arranged regardless of the distance from the cell region edge CRE.

Referring to FIG. 2A, a region where the second contact plugs CT2 are positioned and a region where the first contact plugs CT1 are positioned may overlap. The first contact plugs CT1 and the second contact plugs CT2 may be positioned to correspond to each other. The first contact plugs CT1 may be respectively positioned under the second contact plugs CT2. The first contact plugs CT1 and the second contact plugs CT2 may be arranged to be aligned in a 1 to 1 correspondence (1:1), or may be arranged in a staggered (or offset) manner.

Referring to FIG. 2B, the first contact plugs CT1 and the second contact plugs CT2 may be formed in different regions so as not to overlap. In some embodiments, the first contact plugs CT1 may be positioned closer to the cell region edge CRE compared to the second contact plugs CT2. In other embodiments, the second contact plugs CT2 may be positioned closer to the cell region edge CRE compared to the first contact plugs CT1.

According to the structure described above, the first contact plugs CT1 and the second contact plugs CT2 may be disposed on the front surface FS and the rear surface RS of the gate structure GST, respectively, in a dispersion manner. Therefore, a height of the first contact plugs CT1 and the second contact plugs CT2 may be decreased, and the area of the contact region may be reduced.

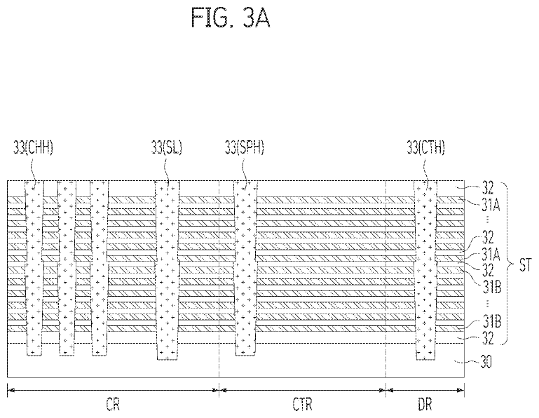

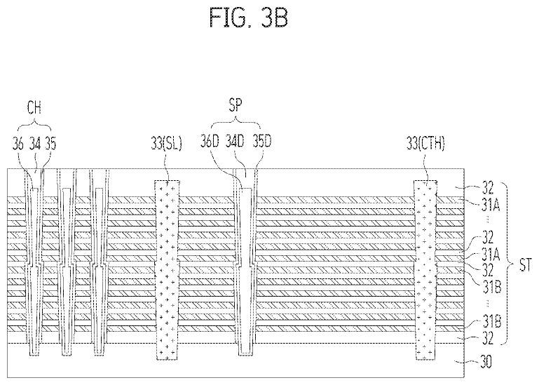

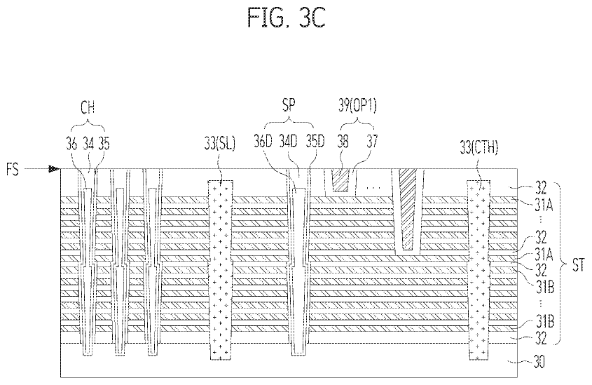

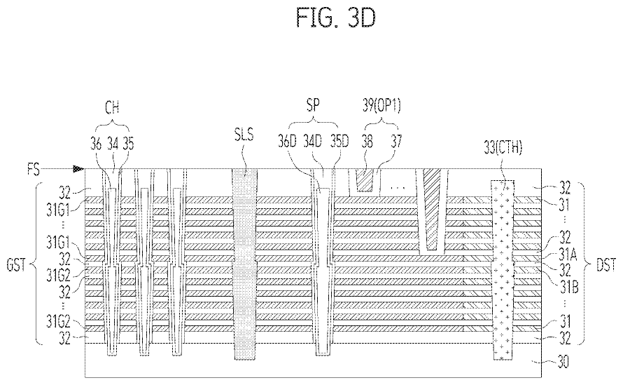

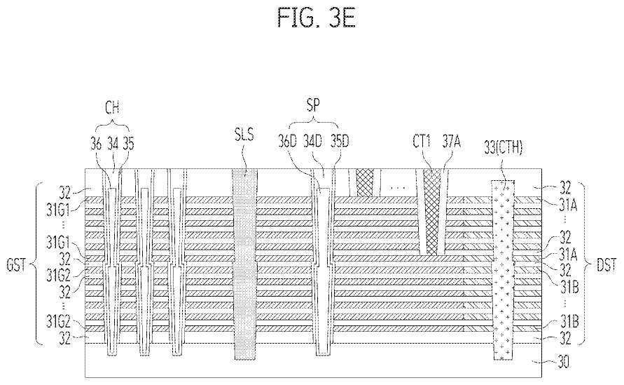

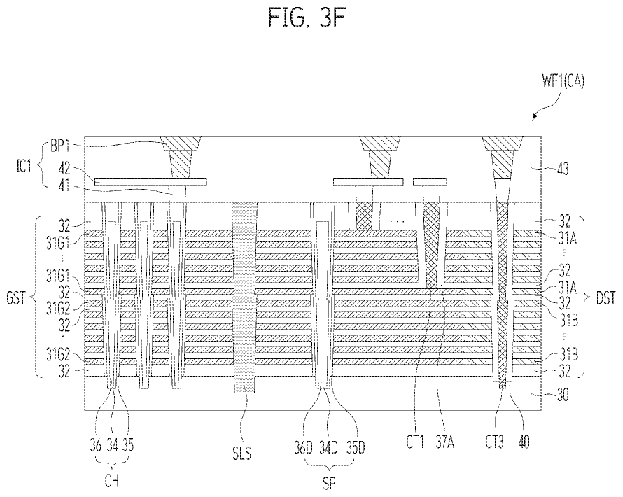

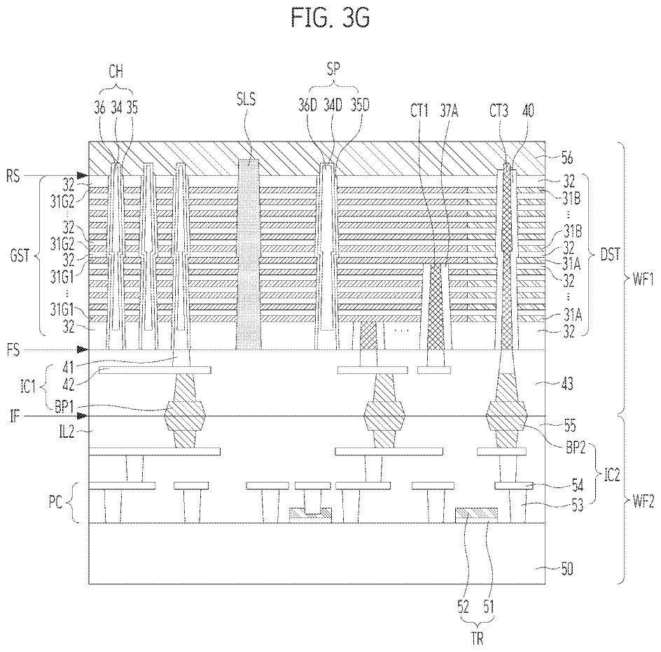

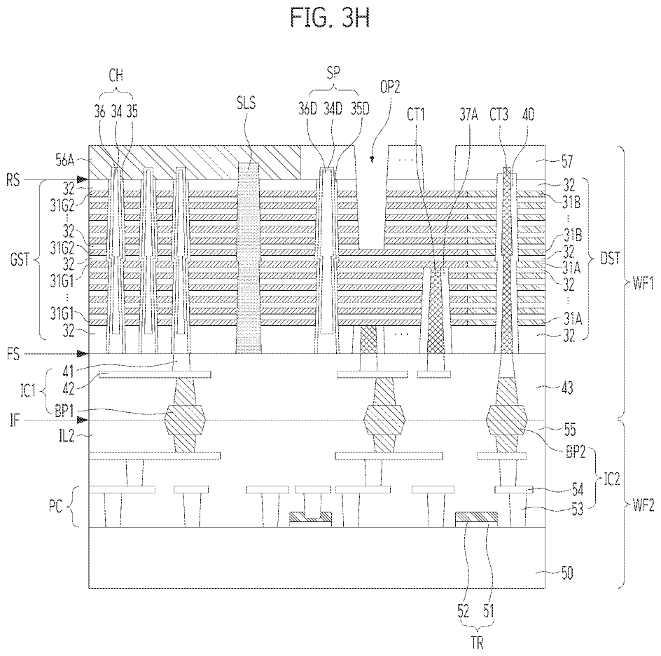

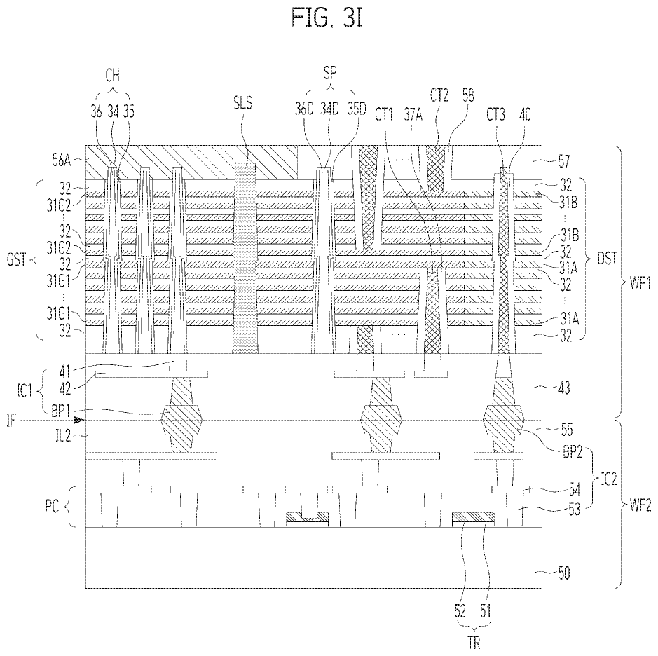

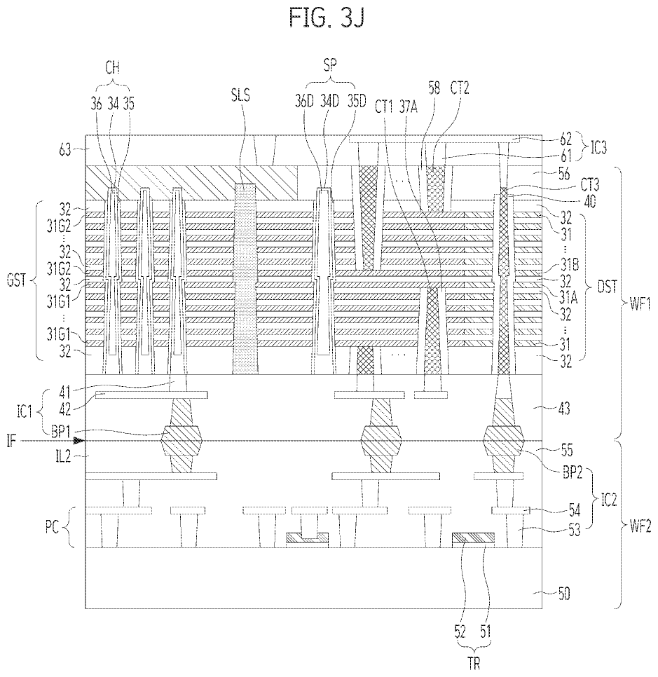

FIGS. 3A to 3J are simplified diagrams illustrating a method of manufacturing a semiconductor device according to an embodiment of the present disclosure. Hereinafter, a description overlapping a content described above may be omitted.

Referring to FIG. 3A, a stack ST may be formed over or on a substrate 30. The stack ST may include a cell region CR, a contact region CTR, and a dummy region DR. The dummy region DR may be a region where a dummy stack is to be formed in a subsequent process. The stack ST may include stacked first material layers 31A and stacked second material layers 31B. In some embodiments, after forming a first group of the second material layers 31B and insulating layers 32 alternately stacked on the substrate 30, then a second group of the first material layers 31A and insulating layers 32 alternately stacked may be formed overlapping with the first group.

The first material layers 31A and the second material layers 31B may include a material with a high etch selectivity with respect to the insulating layers 32. The first material layers 31A and the second material layers 31B may be sacrificial layers including nitride, or may be conductive layers including a conductive material such as polysilicon, tungsten, or molybdenum. The insulating layers 32 may include an insulating material such as oxide or nitride.

Subsequently, at least one of a channel hole CHH, a slit SL, a support hole SPH, and a contact hole CTH may be formed. The channel hole CHH, the slit SL, the support hole SPH, and the contact hole CTH may extend into the substrate 30 through the stack ST. Subsequently, a sacrificial layer 33 may be formed in the channel hole CHH, the slit SL, the support hole SPH, and the contact hole CTH. The sacrificial layer 33 may include a material with a high etch selectivity with respect to the first material layers 31A, the second material layers 31B, and the insulating layers 32.

Referring to FIG. 3B, at least one of the channel holes CHH and the support holes SPH may be reopened. In some embodiments, the insulating layer 32 may be formed on the stack ST to cover the sacrificial layers 33. Subsequently, a mask pattern covering the slit SL and the contact hole CTH and exposing the channel holes CHH and the support hole SPH may be formed on the insulating layer 32, and the sacrificial layers 33 may be selectively removed. Through this, the channel holes CHH and the support holes SPH may be selectively reopened.

Subsequently, a channel structure CH may be formed in the channel holes CHH. The channel structure CH may include at least one of a channel layer 34, a memory layer 35, and an insulating core 36. When forming the channel structure CH, the support SP may be formed in the support hole SPH. The support SP may include at least one of a dummy channel layer 34D, a dummy memory layer 35D, and a dummy insulating core 36D. Through this, the channel structure CH and the support SP extending through the stack ST may be formed.

Referring to FIG. 3C, sacrificial contact structures 39 may be formed. In some embodiments, first openings OP1 respectively exposing the first material layers 31A may be formed in the stack ST. Front surfaces of the first material layers 31A may be exposed through the first openings OP1.

Subsequently, the sacrificial contact structure 39 may be formed in each first opening OP1. The sacrificial contact structure 39 may include a sacrificial contact layer 38 and an insulating liner 37 surrounding the sacrificial contact layer 38. In some embodiments, the insulating liner 37 may be formed conformally on the walls of the first openings OP1, and the sacrificial contact layer 38 may be formed in a remaining central space inside the first openings OP1 which is not covered by the insulating liner 37. Subsequently, a planarization process may be performed on the stack ST until a front surface FS of the stack ST is formed to expose the sacrificial contact layers 38 and the insulating liners 37 which are positioned in the first openings OP1.

Referring to FIG. 3D, after exposing the sacrificial layer 33 formed in the slit SL, the sacrificial layer 33 may be removed to reopen the slit SL. Subsequently, the first material layers 31A and the second material layers 31B may be replaced with conductive layers through the slit SL. The first material layers 31A may be replaced with first gate lines 31G1, and the second material layers 31B may be replaced with second gate lines 31G2. Through this, a gate structure GST including the stacked first gate lines 31G1 and the stacked second gate lines 31G2 may be formed. During a replacement process, the first material layers 31A and the second material layers 31B may remain in a partial region without being replaced. A portion where the first material layers 31A and the second material layers 31B remain may be defined as the dummy stack DST.

When the first material layers 31A and the second material layers 31B are conductive layers, the replacement process may not be performed. In this case, the first material layers 31A may be used as the first gate lines 31G1, the second material layers 31B may be used as the second gate lines 31G2, and the stack ST may be used as the gate structure GST.

Subsequently, a slit structure SLS may be formed in the slit SL. The slit structure SLS may include at least one of an insulating material, a conductive material, and a semiconductor material. In some embodiments, the slit structure SLS may include a gap-fill material such as oxide, nitride, or amorphous silicon. The slit structure SLS may include a source contact structure and an insulating spacer surrounding a sidewall of the source contact structure.

Referring to FIG. 3E, the sacrificial contact layers 38 may be removed to reopen the first openings OP1. Subsequently, the insulating liners 37 may be etched to form first insulating spacers 37A. Subsequently, first contact plugs CT1 may be formed in the first openings OP1. The first contact plugs CT1 may extend in different depths through the front surface FS of the gate structure GST and may be respectively connected to front surfaces of the first gate lines 31G1.

Referring to FIG. 3F, after exposing the sacrificial layer 33 formed in the contact hole CTH (see FIG. 3E), the sacrificial layer 33 may be removed to reopen the contact hole CTH and, subsequently, a third contact plug CT3 may be formed in the contact hole CTH. As shown in FIG. 3F, the third contact plug CT3 may be formed after forming a third insulating spacer 40 on an inner wall of the contact hole CTH. Through these operations, the third contact plug CT3 extending through the dummy stack DST may be formed.

Subsequently, a first interconnection structure IC1 and a first interlayer insulating layer 43 may be formed. The first interconnection structure IC1 may be positioned in the first interlayer insulating layer 43. The first interlayer insulating layer 43 may be a single layer or multiple layers. The first interconnection structure IC1 may be connected to at least one of the channel structure CH, the first contact plug CT1, and the third contact plug CT3. The first interconnection structure IC1 may include at least one via 41 and at least one conductive line 42. The first interconnection structure IC1 may include a first bonding pad BP1. Through this, a first wafer WF1 including the substrate 30, the gate structure GST, and the first contact plugs CT1 may be manufactured. The first wafer WF1 may include a cell array CA.

Referring to FIG. 3G, a peripheral circuit PC may be formed over or on a substrate 50. The peripheral circuit PC may, for example, include a row decoder, a page buffer, an input/output circuit, and the like. The transistor TR may include a gate insulating layer 51 and a gate electrode 52. Subsequently, a second interconnection structure IC2 and a second interlayer insulating layer 55 may be formed. The second interconnection structure IC2 may be positioned in the second interlayer insulating layer 55. The second interlayer insulating layer 55 may be a single layer or multiple layers. The second interconnection structure IC2 may be connected to the peripheral circuit PC. The second interconnection structure IC2 may include at least one via 53 and at least one conductive line 54. The second interconnection structure IC2 may include a second bonding pad BP2. Through this, a second wafer WF2 including the peripheral circuit PC may be manufactured.

Subsequently, the first wafer WF1 and the second wafer WF2 may be bonded to each other. The first wafer WF1 and the second wafer WF2 may be bonded so that the front surface FS of the gate structure GST and the peripheral circuit PC face each other. The first bonding pad BP1 and the second bonding pad BP2 may be bonded, and the first interlayer insulating layer 43 and the second interlayer insulating layer 55 may be bonded to form a bonding interface IF.

Subsequently, the substrate 30 may be removed. Through this, a rear surface RS of the gate structure GST may be exposed. Subsequently, the memory layer 35 of the channel structure CH exposed through the rear surface of the gate structure GST may be etched to expose the channel layer 34.

Subsequently, a source layer 56 may be formed over or on the rear surface of the gate structure GST. The source layer 56 may include a conductive material such as polysilicon or metal. For reference, the channel layer 34 may be doped with an impurity before forming the source layer 56.

Referring to FIG. 3H, the source layer 56 may be etched to form a source structure 56A. In some embodiments, the source layer 56 may be etched to expose a region where the first contact plugs CT1 are formed. Through this, the source structure 56A may be formed on the rear surface of the gate structure GST. The source structure 56A may cover or expose the dummy stack DST. Subsequently, an insulating layer 57 may be formed in a region where the source layer 56 is etched.

Subsequently, second openings OP2 respectively exposing the second material layers 31B may be formed. The second openings OP2 may pass through the insulating layer 57 and extend into the gate structure GST through the rear surface RS of the gate structure GST. Rear surfaces of the second gate lines 31G2 may be respectively exposed through the second openings OP2.

Referring to FIG. 3I, second insulating spacers 58 may be formed conformally inside the second openings OP2. Second contact plugs CT2 may be formed in the space not filled by the second insulating spacers 58 inside the second openings OP2. Hence, second contact plugs CT2 positioned on the first contact plugs CT1 may be formed.

Referring to FIG. 3J, a third interconnection structure IC3 and a third interlayer insulating layer 63 may be formed. The third interconnection structure IC3 may be positioned in the third interlayer insulating layer 63. The third interlayer insulating layer 63 may be a single layer or multiple layers. The third interconnection structure IC3 may be connected to at least one of the second contact plugs CT2 and the third contact plugs CT3. The third interconnection structure IC3 may include at least one via 61 and at least one conductive line 62.

According to the manufacturing method described above, the first contact plugs CT1 and the second contact plugs CT2 may be formed on the front surface FS and the rear surface RS of the gate structure GST in a dispersion manner. Therefore, an aspect ratio of the first openings OP1 and the second openings OP2 may be reduced, and process difficulty may be reduced. By forming the first contact plugs CT1 and the second contact plugs CT2 separately before and after wafer bonding, the first contact plugs CT1 and the second contact plugs CT2 may be stacked vertically. Therefore, the area of the contact region may be reduced.

Although embodiments according to the technical spirit of the present disclosure have been described with reference to the accompanying drawings, this is only for describing an embodiment according to the technical concepts of the present disclosure, and the present disclosure is not limited to the above-described embodiments. Within the scope of the technical concepts of the present disclosure, various forms of substitution, modification, and change of the embodiments will be possible by those skilled in the art to which the present disclosure belongs, and these also belong to the scope of the present disclosure.

What is claimed is:

1. A semiconductor device comprising:
a first group of stacked first gate lines, and a second group of stacked second gate lines overlapping with the first group of the first stacked lines, the first and second groups being spaced apart from each other, wherein the first gate lines and the second gate lines alternate with insulation layers;
a channel structure extending through the first gate lines and the second gate lines;
first contact plugs extending through the first gate lines and respectively connected to front surfaces of the first gate lines; and
second contact plugs extending through the second gate lines and respectively connected to rear surfaces of the second gate lines.

2. The semiconductor device of claim 1, wherein the first contact plugs extend in different depths through the first gate lines.

3. The semiconductor device of claim 1, wherein the second contact plugs extend in different depths through the second gate lines.

4. The semiconductor device of claim 1, further comprising:
a dummy stack;
a peripheral circuit; and
a third contact plug extending through the dummy stack and connecting the second contact plugs and the peripheral circuit.

5. The semiconductor device of claim 1, further comprising:
a peripheral circuit; and
an interconnection structure connecting the peripheral circuit to the first contact plugs and the second contact plugs.

6. The semiconductor device of claim 5, wherein the interconnection structure includes a bonding pad.

7. The semiconductor device of claim 1, further comprising:
insulating spacers surrounding sidewalls of the first contact plugs and the second contact plugs, respectively.

8. The semiconductor device of claim 1, wherein the first contact plugs are positioned under the second contact plugs, respectively.

9. The semiconductor device of claim 1, wherein the first contact plugs have a taper shape cross-section and the second contact plugs have an inverted taper shape cross-section.

10. A semiconductor device comprising:
a peripheral circuit;
a gate structure including a front surface facing the peripheral circuit;
a first contact plug extending into the gate structure through the front surface;
a second contact plug extending into the gate structure through a rear surface; and
an interconnection structure connecting the first contact plug and the second contact plug to the peripheral circuit.

11. The semiconductor device of claim 10, further comprising:
a dummy stack connected to the gate structure; and
a third contact plug extending through the dummy stack and connected to the second contact plug,
wherein the interconnection structure connects the third contact plug and the peripheral circuit.

12. The semiconductor device of claim 10, wherein the interconnection structure includes a bonding pad.

13. The semiconductor device of claim 10, further comprising:
a channel structure extending through the gate structure.

14. The semiconductor device of claim 10, further comprising:
insulating spacers surrounding sidewalls of the first contact plugs and the second contact plugs, respectively.

15. A method of manufacturing a semiconductor device, the method comprising:
forming a gate structure including stacked first gate lines and stacked second gate lines;
forming first contact plugs extending into the gate structure through a front surface and respectively connected to the first gate lines; and
forming second contact plugs extending into the gate structure through a rear surface and respectively connected to the second gate lines.

16. The method of claim 15, wherein forming the gate structure comprises:
forming a stack including a first group of alternately stacked first material layers and insulation layers and a second group of alternately stacked second material layers and insulation layers;
replacing the first material layers with the first gate lines; and
replacing the second material layers with the second gate lines.

17. The method of claim 16, wherein forming the first contact plugs comprises:
forming first openings extending through the stack and respectively exposing the first material layers;
forming sacrificial contact layers in the first openings;
removing sacrificial contact layers after replacing the first material layers with the first gate lines; and
forming the first contact plugs in the first openings.

18. The method of claim 17, wherein forming the first contact plugs comprises:
forming insulating liners in the first openings; and
forming first insulating spacers by etching the insulating liners.

19. The method of claim 16, further comprising:
forming a channel structure extending through the stack.

20. The method of claim 16, further comprising:
forming a third contact plug extending through the stack.

21. The method of claim 20, further comprising:
forming an interconnection structure connecting the second contact plugs and the third contact plug.

22. The method of claim 15, further comprising:
bonding a first wafer including a substrate, the gate structure, and the first contact plugs, and a second wafer including a peripheral circuit; and
exposing the rear surface of the gate structure by removing the substrate.

23. The method of claim 22, further comprising:
forming a source structure on the rear surface of the gate structure.

24. The method of claim 23, wherein forming the source structure comprises:
forming a source layer on the rear surface of the gate structure; and
etching the source layer to expose a region where the first contact plugs are formed.

25. The method of claim 15, wherein forming the second contact plugs comprises:
forming second openings extending through the rear surface and respectively exposing the second gate lines;
forming second insulating spacers in the second openings; and
forming the second contact plugs in the second openings.
